(19) United States
(12) Patent Application Publication
(10) Pub. No.: US 2007/0109750 A1
(43) Pub. Date: May 17, 2007

(54) INTEGRATED CIRCUIT PACKAGE SYSTEM

(75) Inventors: Myung Kil Lee, Singapore (SG); Flynn Carson, Singapore, CA (SG)

Correspondence Address: ISHIMARU & ZAHRT LLP, 333 W. EL CAMINO REAL, SUITE 330, SUNNYVALE, CA, 94087, US

(73) Assignee: STATS ChipPAC Ltd., Singapore (SG)

(21) Appl. No.: 11/380,587

(22) Filed: Apr. 27, 2006

Related U.S. Application Data
(60) Provisional application No. 60/594,712, filed on Apr. 29, 2005.

(51) Int. Cl. H05K 7/20

(52) U.S. Cl. 361/719; 361/720; 361/704

(57) ABSTRACT

An integrated circuit package system is provided forming a substrate having an integrated circuit die attached thereon, attaching a heat slug on the substrate, the heat slug having a planar top surface and an opening in the planar top surface, and molding the heat slug and the substrate through the opening.

### CROSS-REFERENCE TO RELATED APPLICATION

This application claims the benefit of U.S. Provisional Patent Application Ser. No. 60/594,712 filed Apr. 29, 2005, and the subject matter thereof is hereby incorporated herein by reference thereto.

### TECHNICAL FIELD

The present invention relates generally to integrated circuit packages and more particularly to integrated circuit packages with a heat sink.

### BACKGROUND ART

Every new generation of integrated circuits with increased operating frequency, performance and the higher level of large scale integration have underscored the need for back-end semiconductor manufacturing to increase the heat management capability within an encapsulated package. It is well acknowledged that when a semiconductor device becomes denser in term of electrical power consumption per unit volume, heat generated is also increases correspondingly. More and more packages are now designed with an external heat sink or heat slug to enhance the ability of heat being dissipated to the package ambient environment. As the state of the art progresses, the ability to adequately dissipate heat is often a constraint on the rising complexity of package architecture design, smaller footprint, higher device operating speed and power consumption.

Modern electronics, such as smart phones, personal digital assistants, location based services devices, enterprise class servers, or enterprise class storage arrays, are packing more integrated circuits into an ever shrinking physical space with expectations for decreasing cost. Contemporary electronics expose integrated circuits and packages to more demanding and sometimes new environmental conditions, such as cold, heat, and humidity requiring integrated circuit packages to provide robust thermal management structures.

As more functions are packed into the integrated circuits and more integrated circuits into the package, more heat is generated degrading the performance, the reliability and the life time of the integrated circuits. Numerous technologies have been developed to meet these requirements. Some of the research and development strategies focus on new package technologies while others focus on improving the existing package technologies. Research and development in the existing package technologies may take a myriad of different directions.

One proven way to reduce cost is to use mature package technologies with existing manufacturing methods and equipments. Paradoxically, the reuse of existing manufacturing processes does not typically result in the reduction of package dimensions. Existing packaging technologies struggle to cost effectively meet the ever demanding thermal requirements of today's integrated circuits and packages. Most integrated circuit devices use molded plastic epoxy as an epoxy mold compound (EMC) for protecting package. But the poor heat dissipation property of EMC sometimes leads to device malfunctions. Current package profiles have not been reduced below 0.8 mm.

Thus, a need still remains for an integrated circuit package system providing low cost manufacturing, improved reliability, increased thermal performance, and reduced integrated circuit package dimensions below 0.8 mm. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including forming a substrate having an integrated circuit die attached thereon, attaching a heat slug on the substrate, the heat slug having a planar top surface and an opening in the planar top surface, and molding the heat slug and the substrate through the opening.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package system in an embodiment of the present invention;

FIG. 2 is a plan view of a heat slug in an embodiment of the present invention;

FIG. 3 is a cross-sectional view of the heat slug along the segment line 3-3′ of FIG. 2;

FIG. 4 is a close-up view of a first opening of the heat slug in an embodiment of the present invention;

FIG. 5 is a close-up view of a second opening of the heat slug in an alternative embodiment of the present invention;

FIG. 6 is a substrate structure in an embodiment of the present invention;

FIG. 7 is the structure of FIG. 6 in a die-attach phase;

FIG. 8 is the structure of FIG. 7 in a first interconnect-attach phase;

FIG. 9 is the structure of FIG. 8 in a slug-attach phase;

FIG. 10 is the structure of FIG. 9 in a molding phase;

FIG. 11 is a more detailed view of the opening in the structure of FIG. 10 in the molding phase;

FIG. 12 is the structure of FIG. 10 with a center gate mold;

FIG. 13 is the structure of FIG. 12 in a second interconnect-attach phase;

FIG. 14 is the structure of FIG. 13 in a singulation phase; and

FIG. 15 is a flow chart of an integrated circuit package system for manufacture of the integrated circuit package system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material, patterning, exposure, development, etching, cleaning, molding, and/or removal of the material or as required in forming a described structure.

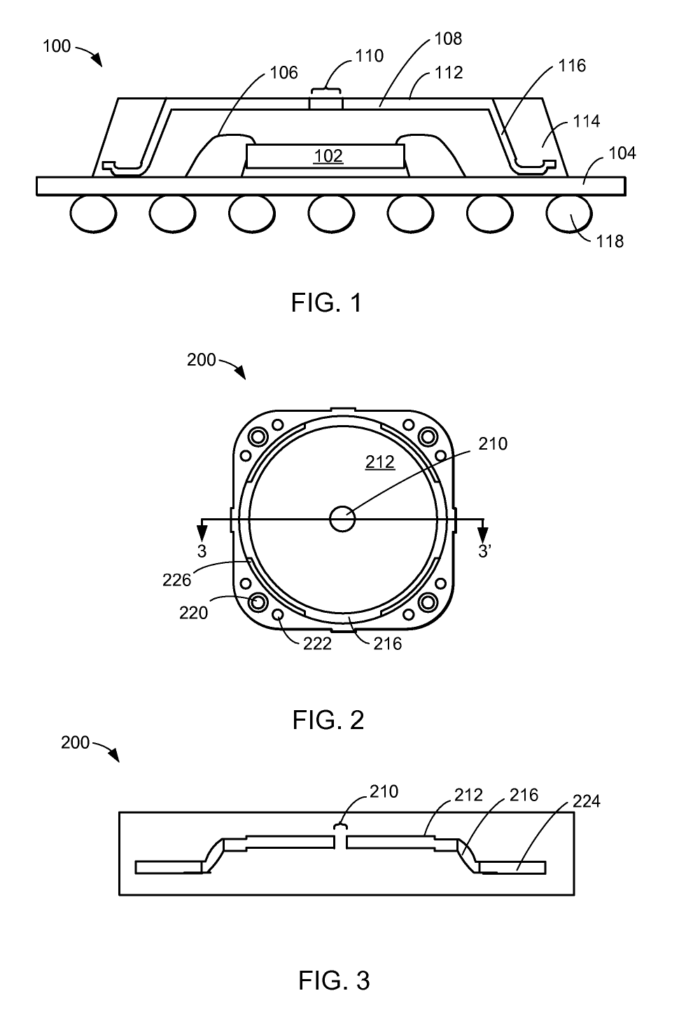

Referring now to FIG. 1, therein is shown a cross-sectional view of an integrated circuit package system 100 in an embodiment of the present invention. The integrated circuit package system 100, such as a thermally enhanced ball grid array (TEBGA) package, provides a high thermal performance management system. An integrated circuit die 102 is on a substrate 104. Internal interconnects 106, such as bond wires or ribbon bonds wires, connect between the integrated circuit die 102 and a top of the substrate 104. A heat slug 108, having an opening 110 is over the integrated circuit die 102 and is on the top of the substrate 104. The opening 110 is coplanar to a planar top surface 112.

An encapsulation 114, such as an epoxy mold compound (EMC), covers the integrated circuit die 102 and the internal interconnects 106. The heat slug 108 is partially covered with the encapsulation 114 with supports 116 of the heat slug 108 covered and the planar top surface 112 of the heat slug 108 exposed to ambient for heat dissipation. External interconnects 118, such as solder balls, are on a bottom of the substrate 104.

The integrated circuit package system 100 provides a number of thermal dissipation paths. For example, the heat may flow from the bottom of the integrated circuit die 102 through the substrate 104 and the external interconnects 118 to the next system level (not shown), such as a printed circuit board, serving as a heat sink. Heat also flows from the integrated circuit die 102 through the encapsulation 114 to the heat slug 108. The heat slug 108 has a higher thermal conductivity than the encapsulation 114 drawing more heat to the heat slug 108. The heat from the heat slug 108 dissipates from the planar top surface 112 of the heat slug 108 to ambient improving the thermal performance of the integrated circuit package system 100.

For illustrative purpose, the substrate 104 is shown as a uniform structure, although it is understood that the substrate 104 may not be uniform and may have other structures (not shown), such as conductive traces, conductive layers, or electrical vias. Also for illustrative purpose, the integrated circuit die 102 is shown by itself, although it is understood that other devices and device configurations may also be used in this invention.

Referring now to FIG. 2, therein is shown a plan view of a heat slug 200 in an embodiment of the present invention. The heat slug 200 may represent the heat slug 108 of FIG. 1. The heat slug 200 having an opening 210 on a planar top surface 212 of the heat slug 200 is substantially square with rounded corners. Each corner has a depression 220, in a shape of a circle, and holes 222, substantially located at opposing sides of the depression 220, on a lower region 224 of the heat slug 200. The holes 222 may be help secure the heat slug 200 with the encapsulation 114 of FIG. 1 in the holes 222. The heat slug 200 also includes supports 216 from the lower region 224 to the planar top surface 212. The supports 216 have slots 226 along each of the corner allowing flow of the mold compound of the encapsulation 114 during the molding process.

For illustrative purpose, the planar top surface 212 and an outline formed by the supports 216 are in a circular geometric configuration, although it is understood that the planar top surface 212 and the outline formed by the supports may be different geometric shapes. Also for illustrative purpose, the heat slug 200 is shown in a rectangular geometric shape with rounded corners, although it is understood that the heat slug 200 may be a different a geometric shape.

Referring now to FIG. 3, therein is shown a cross-sectional view of the heat slug 200 along the segment line 3-3′ of FIG. 2. The opening 210 is approximately at the center of the planar top surface 212 and coplanar to the planar top surface 212. The lower region 224 provides surface space securing the heat slug 200 to the substrate 104 of FIG. 1 with the encapsulation 114. The slots 226 of FIG. 2 are in the supports 216 between the lower region 224 and the planar top surface 212. An elevation of the planar top surface 212 above the lower region 224 and the distance between the supports 216 allow a predetermined clearance for the integrated circuit die 102 of FIG. 1 and the internal interconnects 106 of FIG. 1.

For illustrative purpose, the opening 210 is shown as singular, although it is understood that the opening 210 may be more than one. Also for illustrative purpose, the opening 210 is shown with a circular geometric shape, although it is understood that the geometric shape of the opening 210 may be not be circular as long as flow is permitted for the mold compound of the encapsulation 114 of FIG. 1.

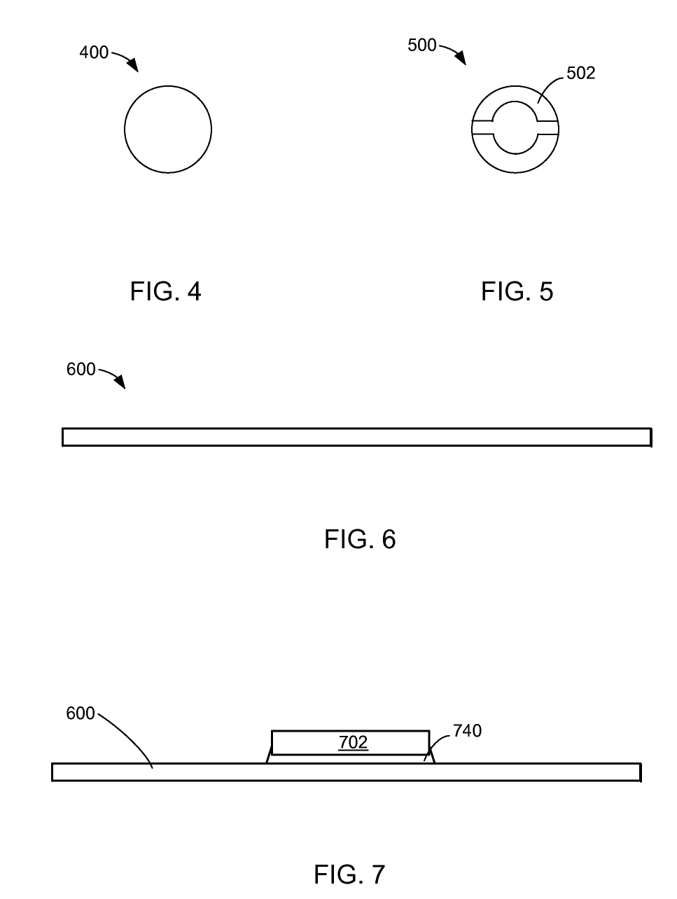

Referring now to FIG. 4, therein is shown a close-up view of a first opening 400 of the heat slug 200 in an embodiment of the present invention. The first opening 400 is a top filling orifice, such as a circular hole traversing the planar top surface 212 of FIG. 2 of the heat slug 200 of FIG. 2. The first opening 400 must be large enough for the molding process apparatus to be discussed in more detail later.

Referring now to FIG. 5, therein is shown a close-up view of a second opening 500 of the heat slug 200 in an alternative embodiment of the present invention. The second opening 500 is also a top filling orifice, such as a downset hole traversing the planar top surface 212 of FIG. 2 of the heat slug 200 of FIG. 2 and has a rim 502 extending towards the substrate 104 of FIG. 1. The second opening 500 must be large enough for the molding process apparatus to be discussed in more detail later and may be any shape providing different flow patterns of the mold compound to accommodate different integrated circuit configurations.

Referring now to FIG. 6, therein is shown a substrate structure 600 in an embodiment of the present invention. The substrate structure 600 includes various structures (not shown), such as signal traces, vias, shields, or insulation. The substrate structure 600 includes a plurality of substrates 104 of FIG. 1 or different substrates.

Referring now to FIG. 7, therein is shown the structure of FIG. 6 in a die-attach phase. An integrated circuit die 702 attaches to the substrate structure 600 with a first adhesive 720, such as a die-attach adhesive. The first adhesive 720 may optionally be cured. The substrate structure 600 with the integrated circuit die 702 may optionally undergo cleaning, such as plasma cleaning. For illustrative purpose, the integrated circuit die 702 is shown as singular, although it is understood that a plurality of integrated circuits and possibly different devices may be attached on the substrate structure 600. Also for illustrative purpose, the integrated circuit die 702 is shown attached with the first adhesive 720, although it is understood that the integrated circuit die 702 may be attached in a different manner, such as solder balls for a flip chip.

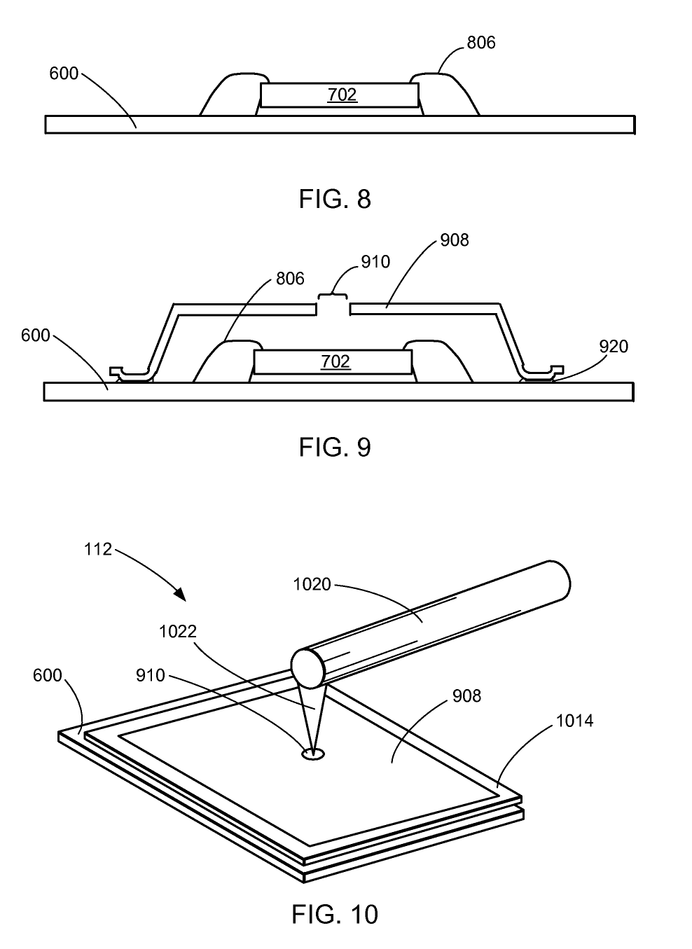

Referring now to FIG. 8, therein is shown the structure of FIG. 7 in a first interconnect-attach phase. Internal interconnects 806, such as bond wires or ribbon bonds, connect between the integrated circuit die 702 and the substrate structure 600 using a number of wire bonding processes, such as wire bonding or ribbon wire bonding. The substrate structure 600 with the internal interconnects 806 may optionally undergo inspection ensuring quality of the connections. This step is optional depending on the type of the integrated circuit die 702, such as a flip chip.

Referring now to FIG. 9, therein is shown the structure of FIG. 8 in a slug-attach phase. A heat slug 908 having an opening 910 attaches on the substrate structure 600 with a second adhesive 920, such as a thermal adhesive, over the integrated circuit die 702 and the internal interconnects 806. The opening 910 is shown over the integrated circuit die 702 and not directly over the internal interconnects 806 to mitigate crossings of the internal interconnects 806 during the molding process to be discussed more later. The substrate structure 600 with the second adhesive 920 may optionally undergo curing.

Referring now to FIG. 10, therein is shown the structure of FIG. 9 in a molding phase. A source 1020 injects a mold compound of an encapsulation 1014 through a gate insert 1022 into the opening 910 of the heat slug 908. The planar surface of the opening 910 forms a proper fit of the gate insert 1022 into the opening 910 without requiring additional fitting structures, such as a rubber washer or a gasket, on the opening 910. The encapsulation 1014 is shown extending beyond the boundary of the heat slug 908. The substrate structure 600 is below the encapsulation 1014 and the heat slug 908. The encapsulation may optionally undergo curing.

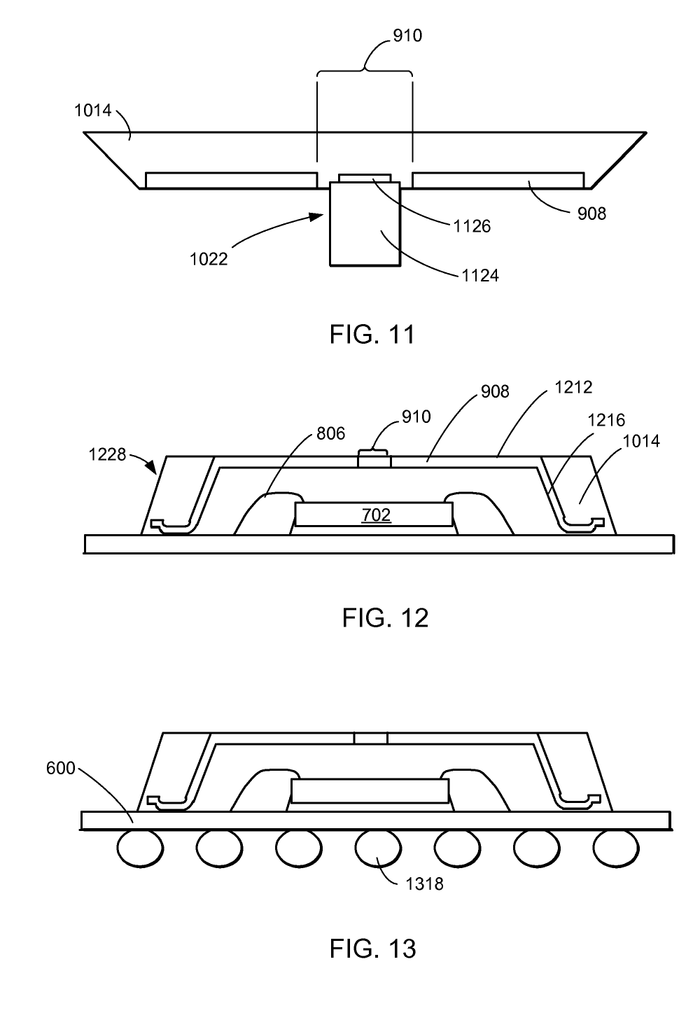

Referring now to FIG. 11, therein is shown a more detailed view of the opening 910 in the structure of FIG. 10 in the molding phase. The gate insert 1022 includes a source connection 1124 and a nozzle 1126. The source connection 1124 connects to the source 1020 of FIG. 10. The gate insert 1022 fits on the heat slug 908 with the nozzle 1126 in the opening 910, wherein the opening 910 funnels the mold compound from the source connection 1124 through the opening 910 forming the encapsulation 1014.

Referring now to FIG. 12, therein is shown the structure of FIG. 10 with a center gate mold 1228. The top molding process with the gate insert 1022 of FIG. 11 forms the center gate mold 1228 covering the integrated circuit die 702, the internal interconnects 806, and supports 1216 of the heat slug 908. A planar top surface 1212 of the heat slug 908 is exposed from the encapsulation 1014.

Referring now to FIG. 13, therein is shown the structure of FIG. 12 in a second interconnect-attach phase. External interconnects 1318, such as solder balls, attach to a bottom side of the substrate structure 600. The external interconnects 1318 form connections to the next system level, such as a printed circuit board or another integrated circuit device.

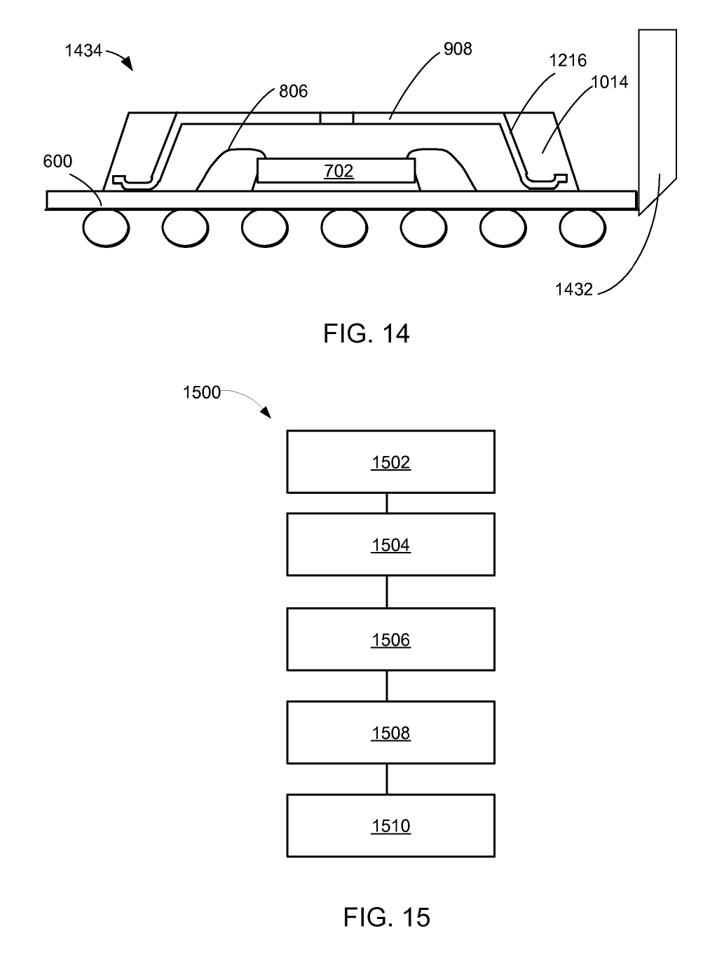

Referring now to FIG. 14, therein is shown the structure of FIG. 13 in a singulation phase. The substrate structure 600 with the encapsulation 1014 covering the integrated circuit die 702, the internal interconnects 806, and the supports 1216 of the heat slug 908 undergoes singulation. A singulation tool 1432, such as a punch or a saw blade, forms an integrated circuit package system 1434. The integrated circuit package system 1434 may be the integrated circuit package system 100 of FIG. 1.

Referring now to FIG. 15, therein is shown a flow chart of an integrated circuit package system 1500 for manufacture of the integrated circuit package system 100 in an embodiment of the present invention. The system 1500 includes forming a substrate having an integrated circuit die attached thereon in a block 1502; attaching a heat slug on the substrate, the heat slug having a planar top surface and an opening in the planar top surface in a block 1504; and molding the heat slug and the substrate through the opening in a block 1506.

It has been discovered that the present invention thus has numerous aspects.

It has been discovered that the present invention provides a thermally enhanced integrated circuit package system having an opening in the heat slug. The heat slug with the opening allows a top center gate molding process increasing the manufacturing yield and lowers cost.

An aspect is that the present invention provides the heat slug with an opening enabling the use of a new mold technology called top center gate mold. The top center gate mold encapsulates the heat slug without sacrificing thermal performance.

Another aspect of the present invention provides the top center gate mold enabled by the heat slug having the opening easing design requirements and allowing use of lower cost processes. For example, longer bond wires may be attached with lower cost bonding processes and equipments. The substrate may be designed with eased constraints for the electrical vias, bond finger pitch, and thinner wires reducing cost.

Yet another aspect of the present invention provides the top center gate mold enabled by the heat slug having the opening allowing use of high K epoxy mold compound that was not previously used due to wire sweep problems.

Thus, it has been discovered that the integrated circuit package system method of the present invention furnishes important and heretofore unknown and unavailable solutions, capabilities, and functional aspects for improving thermal performance and reliability in systems. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
forming a substrate having an integrated circuit die attached thereon;
attaching a heat slug on the substrate, the heat slug having a planar top surface and an opening in the planar top surface; and
molding the heat slug and the substrate through the opening.

2. The system as claimed in claim 1 wherein attaching the heat slug on the substrate, the heat slug having the planar top surface and the opening in the planar top surface includes forming the opening in a configuration of a downset opening.

3. The system as claimed in claim 1 further comprising placing a gate insert in the opening for injection molding.

4. The system as claimed in claim 1 wherein the molding includes forming an encapsulation in a configuration of a center gate mold.

5. The system as claimed in claim 1 molding the heat slug includes molding a support of the heat slug.

6. An integrated circuit package system comprising:
forming a substrate having an integrated circuit die attached thereon with a first adhesive;
attaching a heat slug on the substrate with a second adhesive, the heat slug having a planar top surface and an opening in the planar top surface; and
molding the heat slug, the integrated circuit die, and the substrate through the opening.

7. The system as claimed in claim 6 wherein forming the substrate having the integrated circuit die attached thereon with the first adhesive includes applying a die-attach adhesive for the first adhesive.

8. The system as claimed in claim 6 wherein attaching the heat slug on the substrate with the second adhesive, the heat slug having the planar top surface and the opening in the planar top surface includes applying a thermally conductive adhesive for the second adhesive.

9. The system as claimed in claim 6 further comprising electrically connecting the integrated circuit die and the substrate.

10. The system as claimed in claim 6 further comprising attaching an external interconnect on the substrate.

11. An integrated circuit package system comprising:
a substrate having an integrated circuit die attached thereon;
a heat slug on the substrate, the heat slug having a planar top surface and an opening in the planar top surface; and
an encapsulation to cover the heat slug and the substrate through the opening.

12. The system as claimed in claim 11 wherein the heat slug on the substrate, the heat slug having the planar top surface and the opening in the planar top surface includes the opening in a configuration of a downset opening.

13. The system as claimed in claim 11 wherein the encapsulation to cover the heat slug includes the planar top surface exposed.

14. The system as claimed in claim 11 wherein the encapsulation to cover the heat slug is a center gate mold.

15. The system as claimed in claim 11 wherein the encapsulation to cover the heat slug also covers a support of the heat slug.

16. The system as claimed in claim 11 wherein:
the substrate having the integrated circuit die attached thereon has a first adhesive;
the heat slug on the substrate is attached with a second adhesive, the heat slug having the planar top surface and an opening in the planar top surface; and
the encapsulation to cover the heat slug and the substrate through the opening is also a cover for the integrated circuit die.

17. The system as claimed in claim 16 wherein the first adhesive is a die-attach adhesive.

18. The system as claimed in claim 16 wherein the second adhesive is a thermally conductive adhesive.

19. The system as claimed in claim 16 further comprising an internal interconnect between the integrated circuit die and the substrate.

20. The system as claimed in claim 16 further comprising an external interconnect on the substrate.
